(19) United States
(12) Patent Application Publication
(10) Pub. No.: US 2017/0309759 A1
(43) Pub. Date: Oct. 26, 2017

(54) EPITAXIAL SILICON SOLAR CELLS WITH MOISTURE BARRIER

(71) Applicant: SUNPOWER CORPORATION, San Jose, CA (US)

(72) Inventor: David D. SMITH, Campbell, CA (US)

(73) Assignee: SUNPOWER CORPORATION, San Jose, CA (US)

(21) Appl. No.: 15/643,827

(22) Filed: Jul. 7, 2017

Related U.S. Application Data
(62) Division of application No. 14/040,018, filed on Sep. 27, 2013, now abandoned.

(51) Int. Cl. H01L 31/0216; H01L 31/068; H01L 31/18

(52) U.S. Cl. CPC H01L 31/02167; H01L 31/1804; H01L 31/0682; H01L 31/1892; Y02P 70/521; Y02E 10/547

(57) ABSTRACT

A thin epitaxial silicon solar cell includes one or more layers of doped oxides on the backside. A silicon nitride layer that serves as a moisture barrier is formed on the one or more layers of doped oxides. The doped oxides provide dopants for forming doped regions in an epitaxial silicon layer. Metal contacts are electrically coupled to the doped regions through the silicon nitride layer and the one or more layers of doped oxides.

### CROSS-REFERENCE TO RELATED APPLICATION

This application is a divisional of U.S. patent application Ser. No. 14/040,018, filed on Sep. 27, 2013, which is incorporated herein by reference in its entirety.

### TECHNICAL FIELD

Embodiments of the subject matter described herein relate generally to solar cells. More particularly, embodiments of the subject matter relate to solar cell fabrication processes and structures.

### BACKGROUND

Solar cells are well known devices for converting solar radiation to electrical energy. A solar cell has a front side that faces the sun during normal operation to collect solar radiation and a backside opposite the front side. Solar radiation impinging on the solar cell creates electrical charges that may be harnessed to power an external electrical circuit, such as a load. To compete with other sources of energy, solar cells need to be manufactured at low cost and with high reliability.

### BRIEF SUMMARY

In one embodiment, a thin epitaxial silicon solar cell includes one or more layers of doped oxides on the backside. A silicon nitride layer that serves as a moisture barrier is formed on the one or more layers of doped oxides. The doped oxides provide dopants for forming doped regions in an epitaxial silicon layer. Metal contacts are electrically coupled to the doped regions through the silicon nitride layer and the one or more layers of doped oxides.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. The figures are not drawn to scale.

FIGS. 1-10 show cross-sections that schematically illustrate fabrication of a solar cell in accordance with an embodiment of the present disclosure.

FIGS. 11 and 12 show a flow diagram of a method of fabricating a solar cell in accordance with an embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

“First,” “Second,” etc. As used herein, these terms are used as labels for nouns that they precede, and do not imply any type of ordering (e.g., spatial, temporal, logical, etc.). For example, reference to a “first” doped oxide layer does not necessarily imply that this doped oxide layer is the first doped oxide layer in a sequence; instead the term “first” is used to differentiate this doped oxide layer from another doped oxide layer (e.g., a “second” doped oxide layer).

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

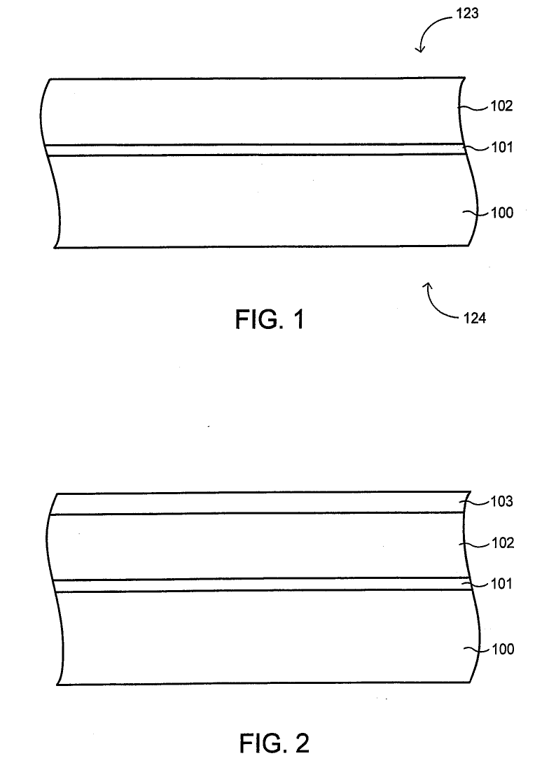

FIGS. 1-10 show cross-sections that schematically illustrate fabrication of a solar cell in accordance with an embodiment of the present disclosure. In the example of FIGS. 1-10, the solar cell being fabricated is a thin epitaxial silicon all back contact solar cell in that the P-type and N-type doped regions of the solar cell and the metal contacts electrically coupled to the P-type and N-type doped regions are on the backside of the solar cell. The substrate of the solar cell being fabricated is an epitaxial silicon layer, instead of a bulk silicon wafer. A solar cell has a plurality of P-type and N-type doped regions but only some of the P-type and N-type doped regions are shown in the figures. Additional P-type and N-type doped regions and other features of the solar cell are not shown for clarity of illustration.

In FIGS. 1-10, the backside of the solar cell being fabricated is on the top of the figures (see FIG. 1, arrow 123) and the front side of the solar cell being fabricated is on the bottom of the figures (see FIG. 1, arrow 124). The front side of the solar cell is also referred to as the “sun side” because it is directed toward the sun during normal operation to collect solar radiation. The backside of the solar cell is opposite the front side.

Referring first to FIG. 1, a sacrificial silicon layer 101 is formed on a backside surface of a source silicon wafer 100. The source silicon wafer 100 may comprise pure silicon, doped, or compound silicon wafer. The source silicon wafer 100 can provide a template for growing the epitaxial silicon layer 102 and facilitates handling of the solar cell during processing of device elements on the backside of the solar cell, such as the subsequently formed P-type and N-type doped regions and metal contacts to the P-type and N-type doped regions. The source silicon wafer 100 is not the substrate of the solar cell and is separated from the solar cell in a subsequent release process.

The sacrificial layer 101 may comprise porous silicon, which may be formed by dipping the backside of the source silicon wafer 100 in a hydrofluoric acid bath with bias. The sacrificial layer 101 may also comprise silicon with, for example, germanium doping and/or a carbon doping, either of which may be formed, for example, by epitaxial deposition or a chemical vapor deposition (CVD) process. The sacrificial layer 101 is relatively thin, e.g., on the order of approximately 700 micrometers, to facilitate subsequent release of the source silicon wafer 100 from the solar cell. As can be appreciated, the thickness and composition of the sacrificial layer 101 may be varied depending on the particulars of the solar cell fabrication process. For example, the sacrificial layer 101 may be as thin as 10 micrometers in some embodiments.

A thin silicon film in the form of an epitaxial silicon layer 102 may be grown directly on the backside surface of the sacrificial layer 101 by a kerfless epitaxial growth process, for example. The epitaxial silicon layer 102 may also be formed by other deposition processes. The epitaxial silicon layer 102 can be referred to as a thin silicon film in that it is relatively thin compared to a bulk silicon wafer. For example, the epitaxial silicon layer 102 may be grown to a thickness of approximately 20 μm to 150 μm (e.g., 50 μm). Use of an epitaxial silicon layer can reduce the fabrication cost of the solar cell but can also present numerous challenges, which can be addressed by the disclosed techniques.

FIG. 2 shows a layer of an oxide P-type dopant source 103 formed on the epitaxial silicon layer 102 on the backside of the solar cell. As its name implies, the oxide P-type dopant source 103 comprises an oxide with P-type dopants (e.g., boron). As will be more apparent below, P-type dopants from the oxide P-type dopant source 103 may be diffused into the epitaxial silicon layer 102 to form P-type doped regions on the backside of the solar cell. In one embodiment, the oxide P-type dopant source 103 comprises borosilicate glass (BSG). The oxide P-type dopant source 103 may also comprise other P-type doped oxides. The oxide P-type dopant source 103 may be formed to a thickness of approximately 1000 Angstroms by atmospheric pressure chemical vapor deposition (APCVD), for example.

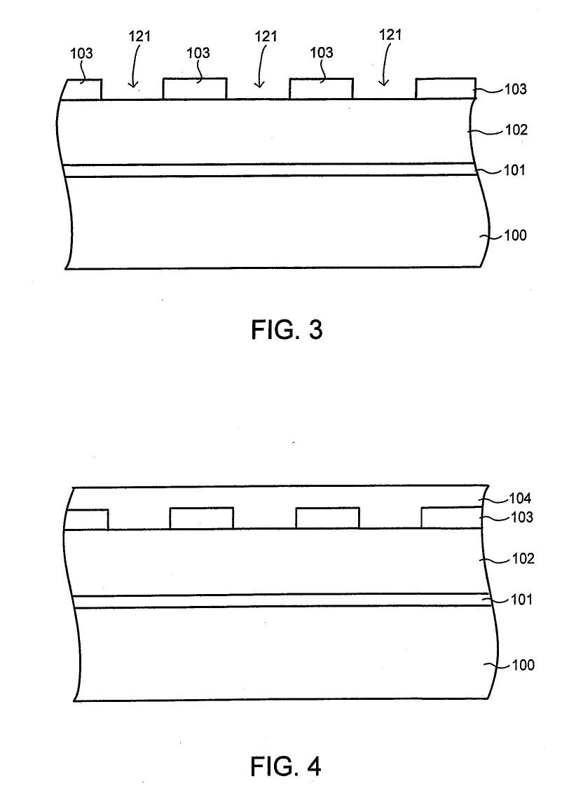

In FIG. 3, the oxide P-type dopant source 103 is patterned to expose portions (see 121) of the epitaxial silicon layer 102. For example, in one embodiment, the oxide P-type dopant source 103 may be patterned by lithography, e.g., masking and etching. The oxide P-type dopant source 103 may also be formed with its pattern already in place. For example, instead of blanket deposition and patterning of the P-type dopant source 103, the P-type dopant source 103 may be applied (e.g., printed) on the epitaxial silicon layer 102 with a pattern that exposes portions of the epitaxial silicon layer 102 as shown in FIG. 3.

FIG. 4 shows a layer of an oxide N-type dopant source 104 formed on the oxide P-type dopant source 103 and on exposed portions of the epitaxial silicon layer 102 between segments of the oxide P-type dopant source 103. As its name implies, the oxide N-type dopant source 104 comprises an oxide with N-type dopants (e.g., phosphorus). N-type dopants from the oxide N-type dopant source 104 may be diffused into the epitaxial silicon layer 102 to form N-type doped regions on the backside of the solar cell. In one embodiment, the oxide N-type dopant source 104 comprises phosphorus silicate glass (PSG). The oxide N-type dopant source 104 may also comprise other N-type doped oxides. The oxide N-type dopant source 104 may be formed to a thickness of approximately 1000 Angstroms by APCVD, for example.

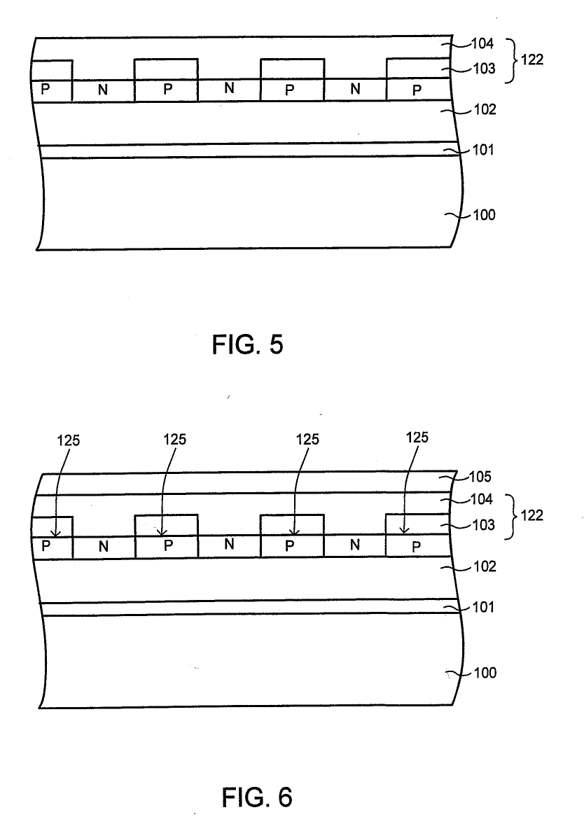

FIG. 5 shows the P-type and N-type doped regions (labeled as “P” and “N”) formed on the backside of the solar cell. In the illustrated embodiment of FIG. 5, P-type dopants from the oxide P-type dopant source 103 can be diffused into the epitaxial silicon layer 102 to form the P-type doped regions in the epitaxial silicon layer 102. Similarly, N-type dopants from the oxide N-type dopant source 104 can be diffused into the epitaxial silicon layer 102 to form the N-type doped regions in the epitaxial silicon layer 102. In one embodiment, the diffusion of P-type and N-type dopants to form the P-type and N-type doped regions, respectively, can be performed at the same time or substantially the same time in situ, such as in the same loading of the solar cell in a diffusion furnace, for example.

FIG. 6 shows a layer of a moisture barrier in the fo in of a silicon nitride 105 formed on the backside of the solar cell, more specifically on the oxide stack 122 comprising the oxide N-type dopant source 104 and the oxide P-type dopant source 103. Moisture penetration through oxides degrades surface passivation, especially on boron doped surfaces. This moisture-induced degradation, which adversely affects reliability and production yield, becomes more pronounced as the coverage of the P-type doped region is increased or as the doping concentration on the surface of the epitaxial silicon layer is decreased. In the example of FIG. 5, the silicon nitride 105 prevents moisture from diffusing through the oxide stack 122 and degrading the passivation on the interface between the oxide P-type dopant source 103 and the epitaxial silicon layer 102 (see FIG. 6, arrow 125). The silicon nitride 105 may be formed to a thickness of approximately 200 to 1000 Angstroms by plasma-enhanced chemical vapor deposition (PECVD), for example. Silicon nitride can be effective in preventing moisture diffusion through boron doped oxides, such as BSG.

In the example of FIG. 6, the silicon nitride 105 is formed directly on the backside surface of the oxide stack 122, i.e., directly on the oxide N-type dopant source 104 on the backside of the solar cell. As can be appreciated, the silicon nitride 105 may also be formed directly on the oxide P-type dopant source 103, especially when the oxide stack 122 consists of a single layer of P-type doped oxide.

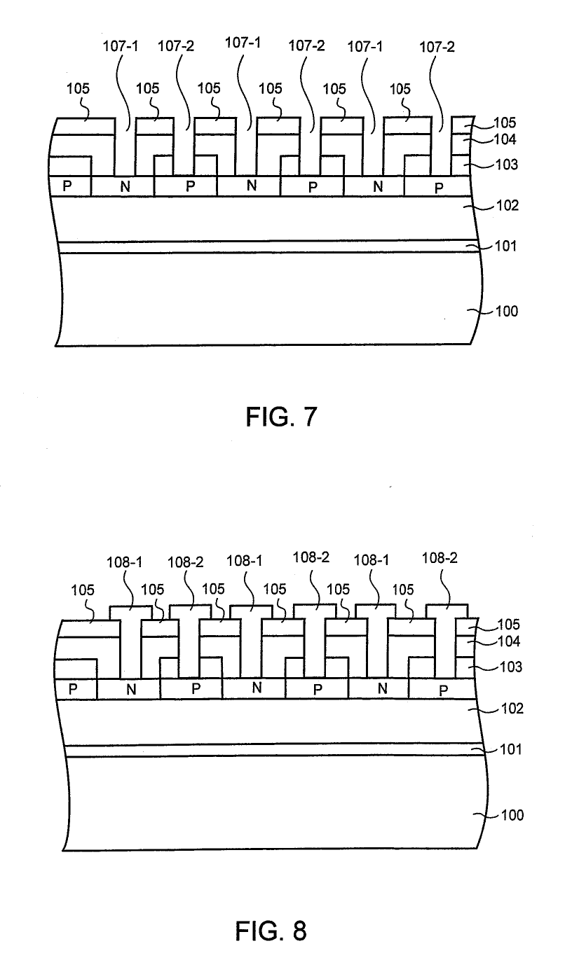

FIG. 7 shows contact openings 107 (i.e., 107-1, 107-2) that expose the P-type and N-type doped regions. In the example of FIG. 7, the contact openings 107-1 are formed through the silicon nitride 105 and the oxide N-type dopant source 104 to expose the N-type doped regions. The contact openings 107-2 are formed through the silicon nitride 105, the oxide N-type dopant source 104, and the oxide P-type dopant source 103 to expose the P-type doped regions. The contact openings 107 may be formed by lithography, laser ablation, and/or other etching/removal processes.

FIG. 8 shows metal contacts 108 (i.e., 108-1, 108-2) that are formed on the backside of the solar cell to electrically connect to the P-type and N-type doped regions. In the example of FIG. 8, the metal contacts 108-1 are formed in the contact openings 107-1 (see FIG. 7), and the metal contacts 108-2 are formed in the contact openings 107-2. In the illustrated embodiment, the metal contacts 108-1 are electrically coupled to N-type doped regions, and the metal contacts 108-2 are electrically coupled to P-type doped regions. The metal contacts 108 may be formed by plating, sputtering, printing, or other metallization process. The source silicon wafer 100 can facilitate handling during processing of the backside of the solar cell, including during formation of the P-type and N-type doped regions and their corresponding metal contacts 108.

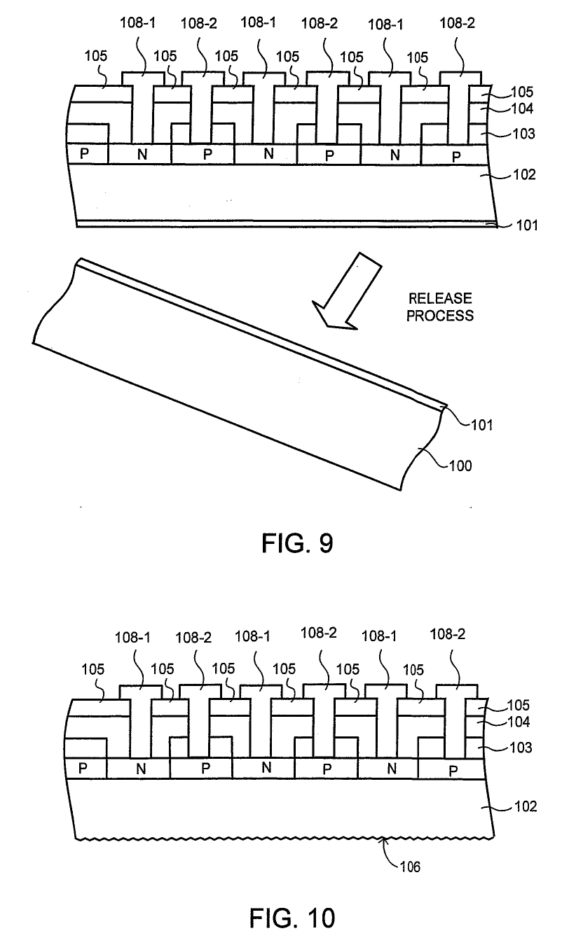

FIG. 9 shows the source silicon wafer 100 being released from the rest of the solar cell. In the example of FIG. 9, a mechanical or electro-chemical release process breaks the sacrificial layer 101 to separate the source silicon wafer 100 from the epitaxial silicon layer 102. The release process may partially or fully destroy the sacrificial layer 101 to release the source silicon wafer 100 from the epitaxial silicon layer 102. The release process may be a selective etch process, including wet etch processes, for example. Portions of the sacrificial layer 101 may remain on the surface of the epitaxial silicon layer 102 and/or the surface of the source silicon wafer 100 after the release process. Sacrificial layer 101 remaining on the source silicon wafer 100 may be re-used to grow another epitaxial silicon layer of another solar cell. In that case, the surface of the sacrificial layer 101 may be washed or cleaned prior to re-use. The sacrificial layer 101 may also be dissolved entirely, and a new sacrificial layer can be formed on the source silicon wafer 100 for subsequent solar cell fabrication.

FIG. 10 shows texturing of the front side surface of the solar cell to form a textured front side surface 106. The texturing process may form random pyramids on the surface of the epitaxial silicon layer 102, or on the surface of the sacrificial layer 101 in the case where the sacrificial layer 101 is not fully removed from the epitaxial silicon layer 102. The texturing process may comprise a wet or dry etch process, including buffered oxide etching (BOE) to create the textured front side surface 106. One etchant that may be used for the texturing process is potassium hydroxide, for example. The textured front side surface 106 may have a regular, repeating pattern, such as triangular or rectangular pyramids, or may have a randomly determined pattern. Metal contact fingers may thereafter be electrically connected to corresponding contact metals 108.

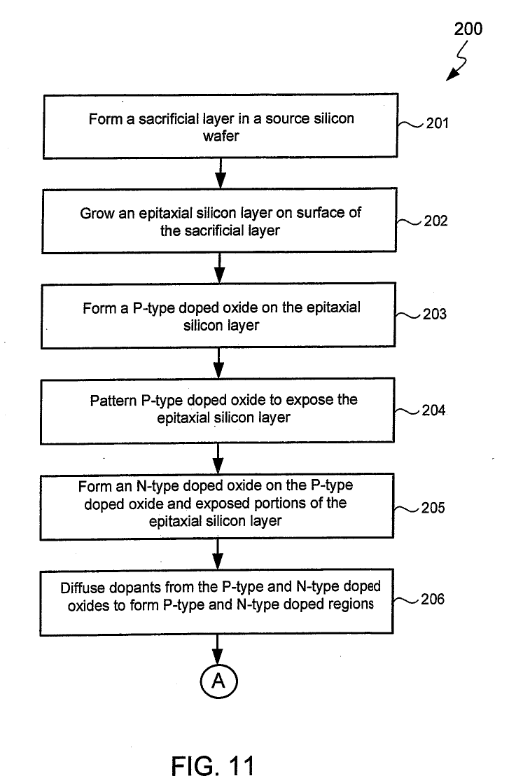

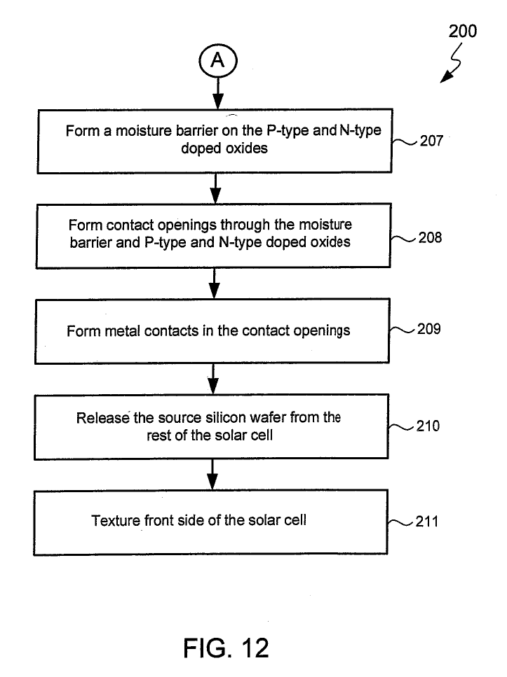

FIGS. 11 and 12 show a flow diagram of a method 200 of fabricating a solar cell in accordance with an embodiment of the present disclosure. FIG. 11 shows the steps 201-206 of the method 200, and FIG. 12 shows the additional steps 207-211. The method 200 may, in some embodiments, include additional or fewer process steps than illustrated.

Referring first to FIG. 11, a sacrificial layer is formed on a source silicon wafer (step 201). The sacrificial layer may comprise porous silicon that is formed on the backside of the source silicon wafer. An epitaxial silicon layer can be grown on the sacrificial layer (step 202). A P-type doped oxide (e.g., BSG) can be formed on the epitaxial silicon layer (step 203), and patterned to expose regions of the epitaxial silicon layer where N-type doped regions are to be formed (step 204). The P-type doped oxide may also have the pattern as formed on the epitaxial silicon layer. For example, the P-type doped oxide may be printed on the epitaxial silicon layer such that the epitaxial silicon layer is exposed between segments of the P-type doped oxide.

An N-type doped oxide (e.g., PSG) can be formed on the P-type doped oxide and on exposed portions of the epitaxial silicon layer between segments of the P-type doped oxide on the backside of the solar cell (step 205). As can be appreciated, in other embodiments where the N-type doped oxide is formed before the P-type doped oxide, the N-type doped oxide can be patterned to expose regions of the epitaxial silicon layer were P-type doped regions are to be formed; the P-type doped oxide is thereafter formed on the N-type doped oxide and on exposed portions of the epitaxial silicon layer between segments of the N-type doped oxide.

P-type dopants (e.g., boron) from the P-type doped oxide are diffused into the epitaxial silicon layer to form P-type doped regions in the epitaxial silicon layer, and N-type dopants (e.g., phosphorus) from the N-type doped oxide are diffused into the epitaxial silicon layer to form N-type doped regions in the epitaxial silicon layer (step 206). The diffusion of both the P-type and N-type dopants into the epitaxial silicon layer may be performed at substantially the same time (e.g., as part of the same loading of the solar cell in a thermal processing apparatus, such as a diffusion furnace).

Continuing in FIG. 12, a moisture barrier comprising silicon nitride can be formed on the P-type and N-type doped oxides on the backside of the solar cell (step 207). In other embodiments, the moisture barrier is formed only on the P-type doped oxide. In some embodiments, the moisture barrier is formed before the contact opening process to ensure that the moisture barrier is conformal. In other embodiments, the moisture barrier can be formed after the contact opening process. The moisture barrier may be formed on the P-type and N-type doped oxides after the diffusion process that forms the P-type and N-type doped regions to prevent high temperature degradation of the moisture barrier.

Contact openings may be formed through the moisture barrier and the P-type and N-type doped oxides to expose the P-type and N-type doped regions (step 208). Depending on the placement of the P-type and N-type doped oxides, a contact opening may be formed through one or both types of doped oxides to expose a corresponding doped region. For example, a contact opening may be formed through the moisture barrier and at least one doped oxide (N-type and/or P-type) to expose a doped region. Metal contacts are thereafter formed in the contact openings on the backside of the solar cell to electrically couple to corresponding doped regions in the epitaxial silicon layer (step 209). The source silicon wafer is released from the rest of the solar cell (step 210), thereby exposing the front side of the solar cell. The front side of the solar cell may be textured thereafter (step 211).

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A method of fabricating a solar cell, the method comprising:
forming an epitaxial silicon layer on a source silicon wafer;
forming an oxide P-type dopant source on the epitaxial silicon layer;
forming a silicon nitride layer on the oxide P-type dopant source;
diffusing P-type dopants from the oxide P-type dopant source into the epitaxial silicon layer to form a P-type doped region in the epitaxial silicon layer; and
releasing the source silicon wafer from the epitaxial silicon layer.

2. The method of claim 1, further comprising:
forming an oxide N-type dopant source on the oxide P-type dopant source; and
diffusing N-type dopants from the oxide N-type dopant source into the epitaxial silicon layer to form an N-type doped region in the epitaxial silicon layer.

3. The method of claim 2, further comprising:
forming a first metal contact to the P-type doped region through at least the silicon nitride layer, the oxide P-type dopant source, and the oxide N-type dopant source.

4. The method of claim 2, further comprising:
forming a second metal contact to the N-type doped region through at least the silicon nitride layer and the oxide N-type dopant source.

5. The method of claim 2, wherein diffusing the P-type dopants into the epitaxial silicon layer to form the P-type doped region and diffusing the N-type dopants into the epitaxial silicon layer to form the N-type doped region are performed in situ at a same time.

6. The method of claim 2, wherein forming the oxide N-type dopant source on the oxide P-type dopant source comprises forming a layer of phosphorus silicate glass on the oxide P-type dopant source.

7. The method of claim 1, wherein forming the oxide P-type dopant source on the epitaxial silicon layer comprises forming a layer of borosilicate glass on the epitaxial silicon layer.

8. The method of claim 1, further comprising:
texturing a front side of the solar cell after releasing the source silicon wafer.

9. A method of fabricating a solar cell, the method comprising:
forming a sacrificial layer on a silicon wafer;
forming, by epitaxial growth process, an epitaxial silicon layer on the sacrificial layer;
forming a first dopant source of a first conductivity type on the epitaxial silicon layer;
forming a second dopant source of a second conductivity type on and through the first dopant source;
diffusing dopants from the first and second dopant sources to the epitaxial silicon layer to form P-type doped regions and N-type doped regions in the epitaxial silicon layer;
forming a layer of silicon nitride on the second dopant source; and
after forming the layer of silicon nitride on the second dopant source, releasing the epitaxial silicon layer from the silicon wafer.

10. The method of claim 9, wherein releasing the epitaxial silicon layer from the silicon wafer comprises:
breaking the sacrificial layer.

11. The method of claim 9, further comprising:
patterning the first dopant source to expose the epitaxial silicon layer.

12. The method of claim 11, wherein the second dopant source is formed through portions of the first dopant source that expose the epitaxial silicon layer.

13. The method of claim 12, wherein the first dopant source is a source of P-type dopants and the second dopant source is a source of N-type dopants.

14. The method of claim 9, further comprising:
after releasing the epitaxial silicon layer from the silicon substrate, texturing a surface of the epitaxial silicon layer.

15. The method of claim 9, further comprising:
forming a plurality of metal contacts through the layer of silicon nitride, the first dopant source, and the second dopant source.

16. A method of fabricating a solar cell, the method comprising:
forming an epitaxial silicon layer on a silicon substrate;
forming alternating P-type and N-type doped regions in the epitaxial silicon layer;
forming a moisture barrier on the P-type and N-type doped regions; and
after forming the moisture barrier, releasing the epitaxial silicon layer from the silicon substrate.

17. The method of claim 16, wherein the moisture barrier comprises silicon nitride.

18. The method of claim 16, further comprising:
before releasing the epitaxial silicon layer from the silicon substrate, forming metal contacts to corresponding P-type and N-type doped regions.

19. The method of claim 18, further comprising:
after releasing the epitaxial silicon layer from the silicon substrate, texturing a surface of the epitaxial silicon layer.

20. The method of claim 19, wherein the epitaxial silicon layer is released from the silicon substrate by breaking a sacrificial layer between the silicon substrate and the epitaxial silicon layer.
